(19) United States
(12) Patent Application Publication
(10) Pub. No.: US 2016/0163736 A1
(43) Pub. Date: Jun. 9, 2016

(54) GATE ARRAY FOR HIGH-SPEED CMOS AND HIGH-SPEED CMOS TTL FAMILY

(71) Applicant: Shivaling Shrishail Mahant Shetti, Belgaum (IN)

(72) Inventors: Shivaling Shrishail Mahant Shetti, Belgaum (IN); Anand Baligatti, Belgaum (IN); Prakash Donur, Bijapur (IN); Veeranna Hooli, Belgaum (IN); Ranganath Y Goudar, Bagalkot (IN); Anil Agasar, Bagalakot (IN); Manjunathreddi G Baragundi, Dharwad (IN)

(21) Appl. No.: 14/963,622

(22) Filed: Dec. 9, 2015

(30) Foreign Application Priority Data
Dec. 9, 2014 (IN) 6222/CHE/2014

(51) Int. Cl. H01L 27/118; H01L 21/8234; H01L 27/11; H01L 21/3213

(52) U.S. Cl. CPC H01L 27/11807; H01L 27/11898; H01L 21/32139; H01L 21/823475; H01L 27/11; H01L 2027/11838

(57) ABSTRACT

A system for implementing an integrated circuit(IC) is provided. The system includes one or more base layers. By using one or more single base layers integrated circuit can be made for a high-speed CMOS (HC) and high-speed CMOS TTL (transistor-transistor logic) compatible (HCT) families. A base layers may be fixed and just one or more metal patterns may be changed for respective integrated circuit (IC). A wafer bank includes large number of transistors to implement one or more circuits by changing the metal pattern required and can make the required circuit.

### CROSS-REFERENCE TO RELATED APPLICATIONS

This application claims priority to Indian patent application no. 6222/CHE/2014 filed on Dec. 9, 2014, the complete disclosure of which, in its entirely, is herein incorporated by reference.

### BACKGROUND

1. Technical Field

The embodiments herein generally relate to integrated circuit and, more particularly, a gate array for high-speed CMOS and high-speed CMOS TTL family. Usually each member of 5 volt digital CMOS families requires many unique layers. The present invention manages to get a large number of such chips keeping all base layers common and getting final functionality by changing only one layer of metal. The resulting chip is extremely small. Manufacturing efficiency due to modularity and lower Silicon costs due to small size are realized. The flexibility of the type of base layer allows manufacture of other silicon systems as well.

2. Description of the Related Art

In semiconductor substrate processing, integrated circuit (IC's) are formed on a substrate (also referred to as a wafer), typically composed of silicon or other semiconductor material. In general, thin film layers of various materials which are either semiconducting, conducting, or insulating are utilized to form the ICs. In prior art, each integrated circuit in HC and HCT series had separate set of base layers and separate masks which increases the cost of production and processing time. It also reduced yield. By using more levels and particularly many higher level metals, there is an increase in the production cost. Accordingly, there remains a need an efficient and cost reduction approach for making full chip with an integrated circuit.

### SUMMARY

In view of the foregoing, an embodiment herein provides a system for implementing an integrated circuit(IC). The system includes one or more base layers. The one or more base layers are processed to implement high-speed CMOS (HC and HCT) families on wafer of silicon semiconductor material. The one or more base layers include one or more transistors and one or more flip-flops. The one or more transistors are used to implement the high-speed CMOS (HC and HCT) families on that wafer with the base layer. Different designs of the high-speed CMOS (HC and HCT) families are obtained by changing only one metal pattern. The metal pattern is processed on the completed wafer by using the metal mask. The base layers have a provision of making one or more flip-flops by using Static Random Accessed Memory (SRAM) cells which are adapted to implement sequential circuits such as (i) a shift register (ii) a counter. The one or more flip-flops use small amount of metal leaving more metal resource for other connections. On the base station, full small systems are made.

In one embodiment, less scarce metal is used for connections on the design of the base layers. In another embodiment, one or more transistors and one or more SRAM based flip-flops, on the wafer of silicon semiconductor material is adapted to implement a decade counter. The decade counter is further interfaced with a seven segment display to provide count value. In another embodiment, the base layer includes a die to communicate to the outside word. The die transistors are arranged to implement (i) an output buffer when the die is an output pin, (ii) an input buffer when the die is an input pin, and (iii) and Input/output (I/O) buffer if the die is the output pin, and the input pin. In another embodiment, the full small systems are formed by using a wafer bank and the base layer and the metal pattern is changed to form many systems.

In one aspect, a method of implementing an integrated circuit(IC) includes the following steps: (i) processing a wafer of silicon semiconductor material with the base layers and storing the wafers after a metal deposit, (ii) the integrated circuit is implemented using one or more transistors, producing high speed CMOS (HC and HCT) families on the processed wafer by changing the metal layer by etching the deposited metal with the metal layer mask, and (iii) by changing only one metal mask, it is possible to implement one or more integrated circuit(IC) on the base layer.

In one embodiment, the base layer includes a die. The die is adapted to implement (i) an output buffer when the die is an output pin, (ii) an input buffer when the die is an input pin, and (iii) an Input/output (I/O) buffer if the die is the output pin, and the input pin.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE DRAWINGS

The embodiments herein will be better understood from the following detailed description with reference to the drawings, in which:

FIG. 1 illustrates a block diagram of integrated circuit in a single die according to an embodiment herein;

FIG. 2 illustrates an exploded view of the integrated circuit of FIG. 1 according to an embodiment herein; and

FIG. 3 illustrates a flow diagram of FIG. 2 according to an embodiment herein.

### DETAILED DESCRIPTION OF PREFERRED EMBODIMENTS

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

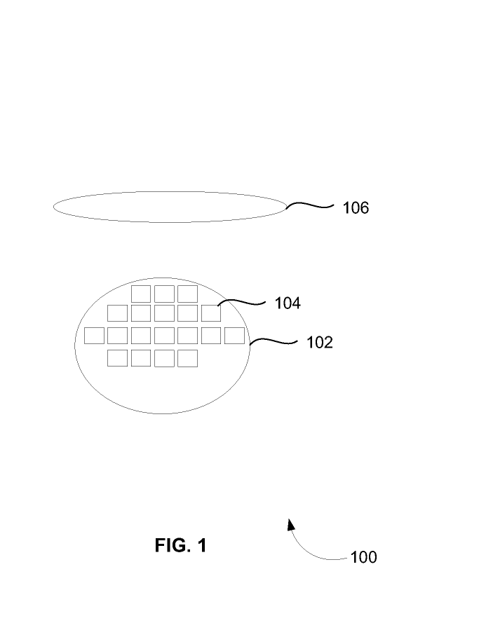

As mentioned, there remains a need for an efficient and cost reduction approach for making full chip with an integrated circuit. By using one or more single base layers integrated circuit can be made for a high-speed CMOS (HC) and high-speed CMOS TTL (transistor- transistor logic) compatible (HCT) families. A base layers may be fixed and just one or more metal patterns may be changed for respective integrated circuit (IC). A wafer bank includes large number of transistors to implement one or more circuits by changing the metal pattern required and can make the required circuit. Referring now to the drawings, and more particularly to FIGS. 1 through 3, where similar reference characters denote corresponding features consistently throughout the figures, there are shown preferred embodiments.

FIG. 1 illustrates a block diagram of integrated circuit 100 in a single die according to an embodiment herein. The block diagram of integrated circuit 100 in a single die includes one or more base layers 102, processed on a wafer of silicon semiconductor material 104, and a metal mask 106. By using one or more base layers 102, integrated circuit 100 can be made for a high-speed CMOS (HC) and high-speed CMOS TTL (transistor-transistor logic) compatible (HCT) families. In the present embodiment one or more base layers 102 may be fixed and just one or more metal patterns may be changed for respective integrated circuit (IC). A wafer bank includes large number of transistors to implement one or more circuits by changing a metal pattern required and can make the required circuit. The solution can be implemented to build a high-speed CMOS (HC) and high-speed CMOS TTL (transistor-transistor logic) compatible (HCT) cells.

In one embodiment, a set of one or more base layers 102 is used to make small systems. For example, using one or more transistors and one or more flip-flops present in a wafer bank a decade counter can be implemented and the decade counters can be interfaced with a seven segment display which displays one or more counts. The one or more transistors and the one or more flip-flops may be made in a single chip if one or more transistors are sufficient. The one or more transistors are arranged to implement (i) an output buffer when a die is an output pin, (ii) an input buffer when said die is an input pin, and (iii) an Input/output (I/O) buffer if said die is the output pin, and the input pin. In one embodiment, many systems can be formed using the wafer bank by just changing metal pattern. In one embodiment, an SRAM (Static Random Accessed Memory) based Flip-Flops placed in each die which is used to make counter or shift register.

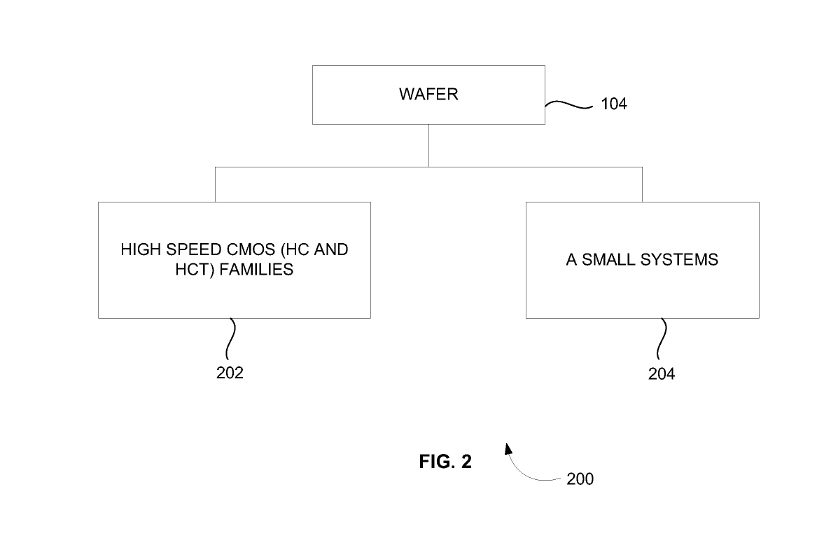

FIG. 2 illustrates an exploded view of the integrated circuit of FIG. 1 according to an embodiment herein. The exploded view of the receiver 200 includes of the wafer of silicon semiconductor material, high speed CMOS (HC and HCT) families 202, and a small systems 204. The small systems 204 are formed using wafer of silicon semiconductor material 104 and one or more base layers 102. The metal pattern changes to form many systems.

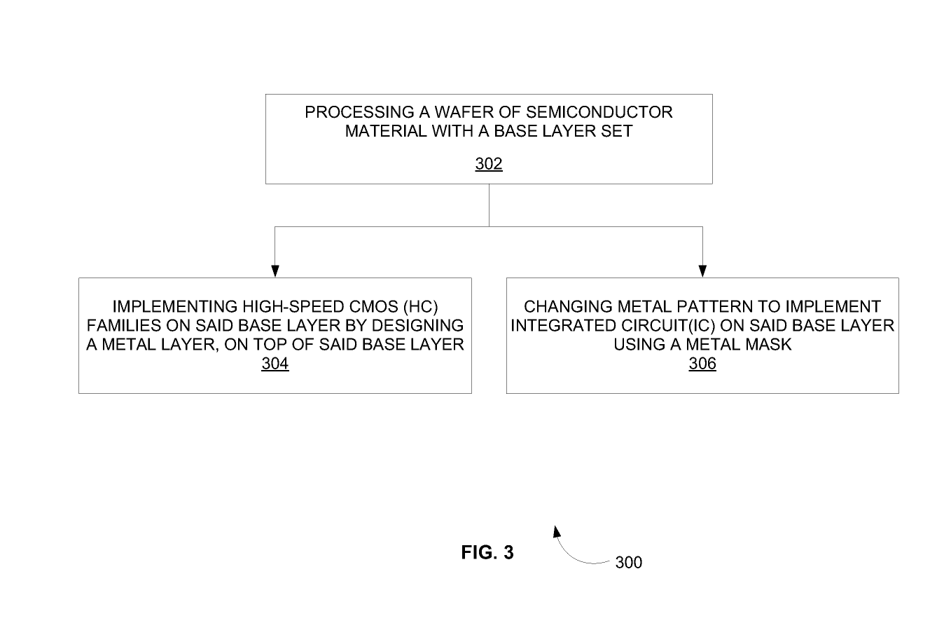

FIG. 3 illustrates a flow diagram 300 of integrated circuit 100 according to an embodiment herein. At step 302, processing a wafer of silicon semiconductor material 104 with one or more base layers 102. The wafer of silicon semiconductor material 104 is stored after a metal deposit. At step 304, implementing high speed CMOS (HC) families on a base layer by designing a metal layer on top of the base layer. High speed CMOS families (HC) is obtained on the wafer of silicon semiconductor 104 by changing only one metal layer by etching the deposited metal with the metal layer mask 106. At step 306, changing metal patterns to implement integrated circuit(IC) 100 on the base layer 102 using a metal layer mask 106. Similar approaches are used in the design of the base layers such that very little of the scarce metal is used to make connections. Care is also taken to ensure when such routine connections are made most of the time they do not block other wires.

This solution provides a better and flexible approach to make a full chip since for each die there may be many output buffers which are used as output if the output die is an output of a circuit. A full chip is that for every chip can have a different base layer or have to start each chip with a scratch but by this wafer bank which can fit all the ICs in the same base layer by just changing the metal masks. As the base layer is same and only the metal patters get changed respectively. Only different is metal masks need to be done for each IC. There is no higher level metals are used. This approach results in cost reduction. As SRAM based flip-flops are used there is a major area reduction. By using this SRAM based flip-flop which provide an option for huge area reduction in the counter and shift register IC's.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the appended claims.

What is claimed is:

1. A system for implementing an integrated circuit (IC), comprising:
a plurality of base layers, wherein said plurality of base layers is processed to implement high-speed CMOS (HC and HCT) families on wafer of silicon semiconductor material, said wafer of said silicon semiconductor material comprising:
a plurality of transistors, wherein said plurality of transistors are implemented on said high-speed CMOS families on said wafer with said plurality of base layers, wherein one or more designs of said high-speed CMOS families are obtained by changing a metal pattern, wherein said metal pattern is processed on said completed wafer using a metal mask,
wherein said plurality of base layers comprising a plurality of flip-flops with Static Random Accessed Memory (SRAM) cells, wherein said plurality of flip-flops is adapted to implement sequential circuits such as (i) a shift register (ii) a counter, wherein said plurality of flip-flops use small amount of metal, leaving more metal resource for other connections, and
wherein on said plurality of base layers, a plurality of small systems is made.

2. The system of claim 1, further comprising a less scarce metal that is used for connections on design on said base layers.

3. The system of claim 1, wherein said plurality of transistors and said plurality of SRAM cells based flip-flops on said wafer of silicon semiconductor material is adapted to implement a decade counter, wherein said decade counter is further interfaced with a seven segment display to provide count value.

4. The system of claim 1, wherein said plurality of base layers comprises a die, wherein said die is arranged to implement (i) an output buffer when said die is an output pin, (ii) an input buffer when said die is an input pin, and (iii) an Input/output (I/O) buffer if said die is said output pin, and said input pin.

5. The system of claim 1, wherein said plurality of small systems are formed using wafer bank and said plurality of base layers, wherein said metal pattern is changed to form one or more systems.

6. A method of implementing an integrated circuit (IC), said method comprising:
processing a wafer of silicon semiconductor material with base layers;
storing said wafer after a metal deposit, wherein said integrated circuit is implemented using said plurality of transistors, wherein said integrated circuit produce high speed CMOS (HC) families on said processed wafer by changing a metal layer;
etching the deposited metal with a metal layer mask; and
changing a metal mask, on said base layers of said integrated circuit, to implement an integrated circuit (IC).

7. The method of claim 6, wherein said base layer comprises a die, wherein said die is adapted to implement (i) an output buffer when said die is an output pin, (ii) an input buffer when said die is an input pin, and (iii) an Input/output (I/O) buffer if said die is said output pin, and said input pin.
